(19) United States
(12) Patent Application Publication
(10) Pub. No.: US 2019/0019869 A1
(43) Pub. Date: Jan. 17, 2019

(54) SEMICONDUCTOR DEVICE AND METHOD FOR MANUFACTURING THE SAME

(71) Applicant: SUPER GROUP SEMICONDUCTOR CO., LTD., Hsinchu County (TW)

(72) Inventors: Hsiu-Wen HSU, Hsinchu County (TW); Chun-Ying YEH, Hsinchu City (TW); Cheng-Ta LO, Hsinchu County (TW); Yuan-Ming LEE, Taichung City (TW)

(21) Appl. No.: 15/888,074

(22) Filed: Feb. 4, 2018

(30) Foreign Application Priority Data
Jul. 12, 2017 (TW) 106123363

(51) Int. Cl. H01L 29/40; H01L 29/423; H01L 29/51

(52) U.S. Cl. CPC H01L 29/407; H01L 29/42336; H01L 29/41741; H01L 29/512; H01L 29/513; H01L 29/401

(57) ABSTRACT

A method for manufacturing a semiconductor device includes the following steps. An epitaxial layer is formed on a substrate. Then, a body is formed in an upper portion of the epitaxial layer. A first dielectric layer, a second dielectric layer, and a third dielectric layer are sequentially formed on the epitaxial layer. The third dielectric layer forms a second trench, and the second trench is located in the first trench. A shield layer is formed in the second trench. The upper portion of the third dielectric layer is removed, such that the upper portion of the shield layer protrudes from the third dielectric layer. A fourth dielectric layer is formed to cover the upper portion of the shield layer. A gate is formed on the third dielectric layer. A source is formed in the epitaxial layer surrounding the gate.

### RELATED APPLICATIONS

This application claims priority to Taiwanese Application Serial Number 106123363, filed Jul. 12, 2017, which is herein incorporated by reference.

### BACKGROUND

### Field of Invention

The present invention relates to a semiconductor device and method for manufacturing the same.

### Description of Related Art

Power semiconductors are main components in many power electronic systems. In current applications of power semiconductors, high energy efficiency, high voltage-endurance, and low on-resistance are important factors, and researchers improve the performance of the power electronic systems by improving characteristics of power components and reducing electrical characteristics of package parasitic capacitance.

In the constant attempt to enhance characteristics of the power semiconductor, there is always a need in the related field to provide a novel power semiconductor having improved characteristics.

### SUMMARY

This disclosure provides a semiconductor device and a method for manufacturing the same, such that the semiconductor device has a larger breakdown voltage and a smaller on-resistance utilizing a properly designed structure. The manufacturing cost of the semiconductor device is reduced accordingly by designing the processes properly.

An aspect of the disclosure provides a method for manufacturing a semiconductor device. The method includes following steps. An epitaxial layer is formed on a substrate, and a body is formed in an upper portion of the epitaxial layer. A first trench is formed in the epitaxial layer. Then a first dielectric layer, a second dielectric layer, and a third dielectric layer are sequentially formed on the epitaxial layer, in which the third dielectric layer defines a second trench, and the second trench is located within the first trench. A shield layer is formed in the second trench. The upper portion of the third dielectric layer is removed, such that the upper portion of the shield layer is protruded from the third dielectric layer. A fourth dielectric layer is formed covering the upper portion of the shield layer. Then a gate is formed on the third dielectric layer, and a source is formed in the epitaxial layer surrounding the gate.

In one or more embodiments of the disclosure, the step of forming the fourth dielectric layer includes performing a thermal oxidation process to the shield layer to form the fourth dielectric layer.

In one or more embodiments of the disclosure, the level of the top surface of the shield layer is between the level of the top surface of the body and the level of the bottom surface of the body.

In one or more embodiments of the disclosure, the method further includes removing an upper portion of the second dielectric layer before forming the gate on the third dielectric layer.

In one or more embodiments of the disclosure, the level of the top surface of the fourth dielectric layer is higher than the level of the top surface of the epitaxial layer.

Another aspect of the disclosure provides a semiconductor device. The semiconductor device includes a substrate, an epitaxial layer disposed on the substrate, a body disposed on an upper portion of the epitaxial layer, a third dielectric layer disposed in a first trench of the epitaxial layer and defining a second trench, a shield layer having an upper portion and a lower portion, in which the lower portion is located in the second trench, and the upper portion is protruded from the third dielectric layer, a fourth dielectric layer covering the upper portion of the shield layer, a gate disposed in the epitaxial layer and on the third dielectric layer, in which at least a part of the fourth dielectric layer is disposed between the upper portion of the shield layer and the gate, and a source disposed in the epitaxial layer surrounding the gate.

In one or more embodiments of the disclosure, at least a part of the gate is disposed above the upper portion of the shield layer.

In one or more embodiments of the disclosure, the semiconductor device further includes a first dielectric layer disposed between the epitaxial layer and the third dielectric layer, and a second dielectric layer disposed between the first dielectric layer and the third dielectric layer. The first dielectric layer includes silicon oxide, and the second dielectric layer includes silicon nitride.

In one or more embodiments of the disclosure, the third dielectric layer comprises tetraethoxysilane (TEOS), and the fourth dielectric layer is formed by thermal oxidizing the shield layer.

In one or more embodiments of the disclosure, the level of the top surface of the shield layer is between the level of the top surface of the body and the level of the bottom surface of the body.

In one or more embodiments of the disclosure, the level of the top surface of the fourth dielectric layer is higher than the level of the top surface of the epitaxial layer.

According to above embodiments, by disposing the shield layer in the epitaxial layer, the shield layer generates a pinch-off effect when the semiconductor device is operated in reverse bias, such that the charge balance and the reduced surface field (RESURF) is generated and a smoother electric field distribution is generated between the substrate and the gate. Therefore, the distance between the substrate and the gate needs to not be large enough to make the semiconductor device have a larger breakdown voltage, and thus the on-resistance of the semiconductor device will be reduced.

In addition, the dielectric layer between the gate and the shield layer is formed by thermal oxidizing the shield layer. Comparing with the traditional manufacturing method, the steps of manufacturing the semiconductor device are further reduced thereby reducing the manufacturing cost.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1G are cross-sectional views of intermediate steps of a method for fabricating a semiconductor device according to an embodiment of this disclosure.

FIGS. 2A to 2C are cross-sectional views of intermediate steps of the method for manufacturing the semiconductor device according to another embodiment of this disclosure.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

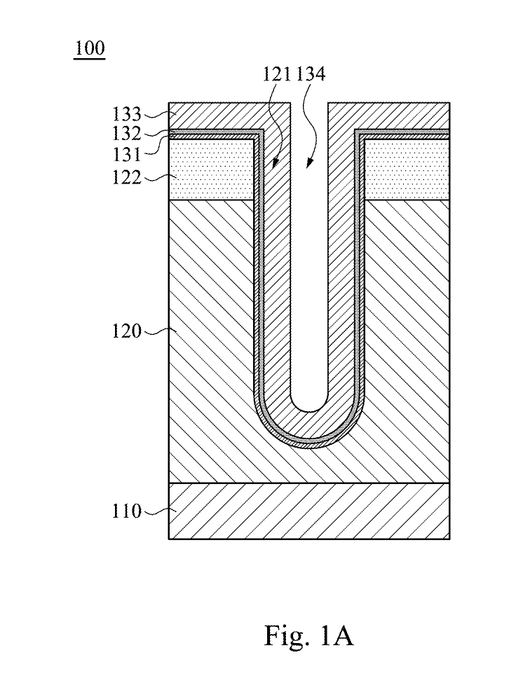

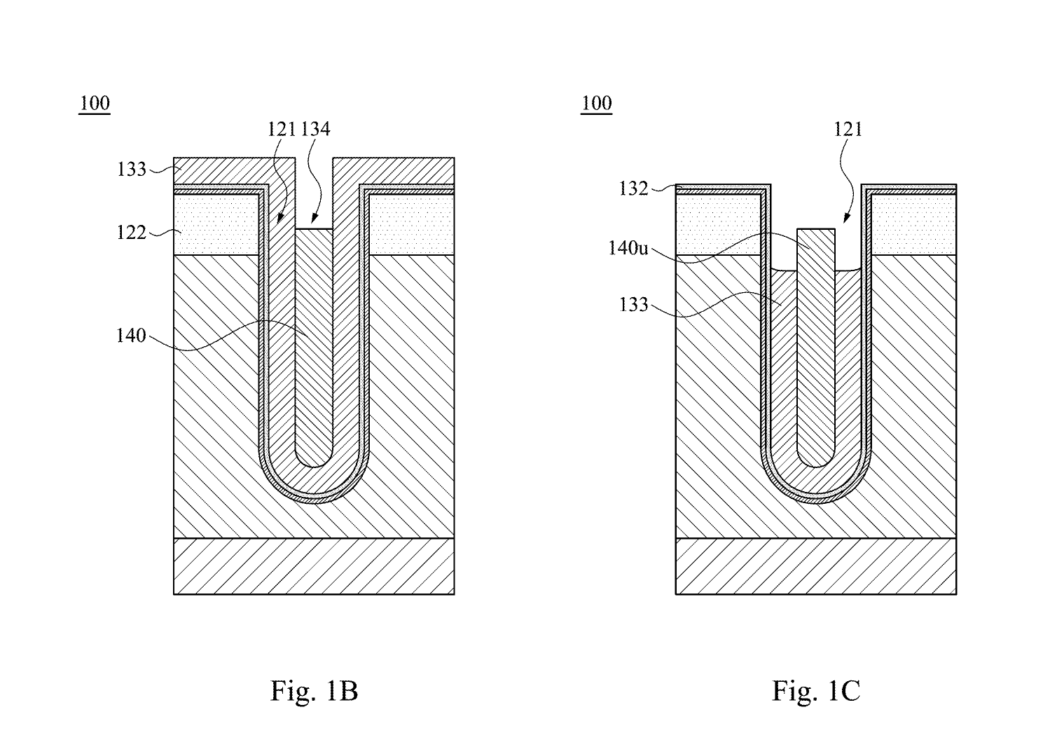

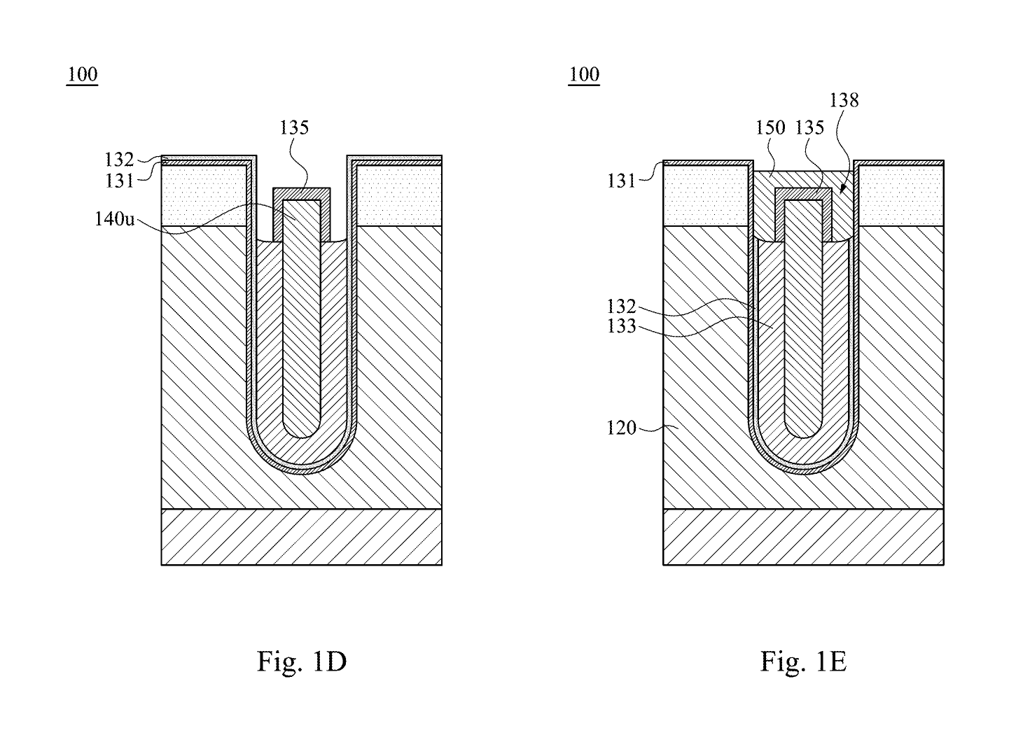

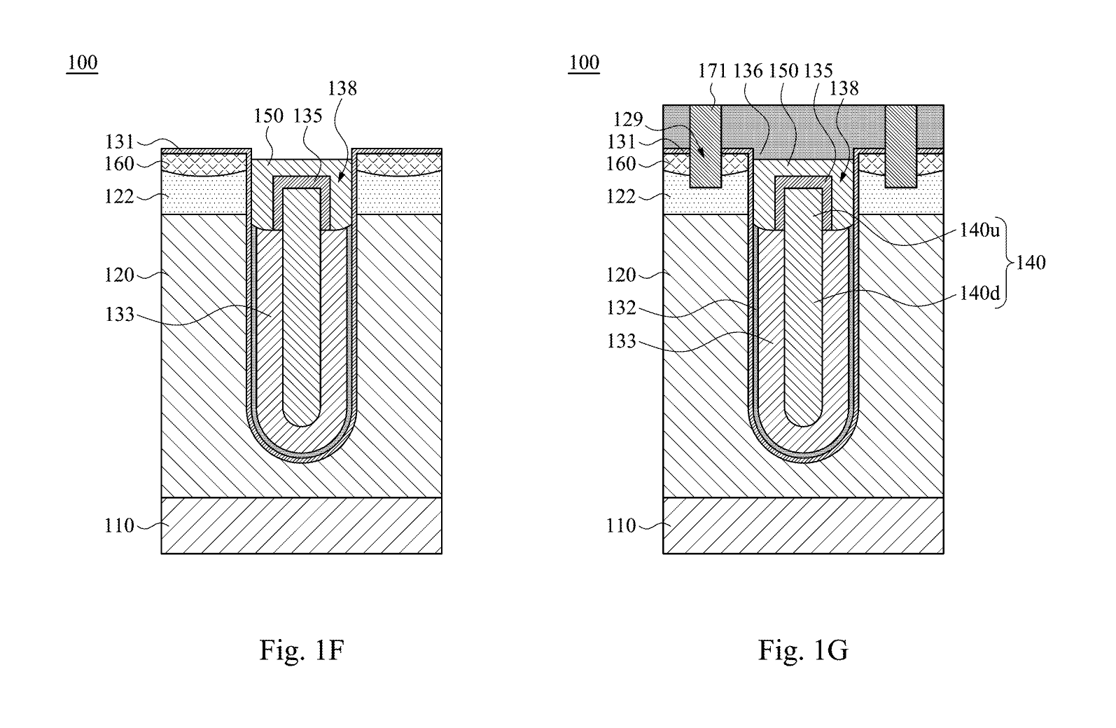

FIGS. 1A to 1G are cross-sectional views of intermediate steps of a method for fabricating a semiconductor device 100 according to an embodiment of this disclosure. For example, the semiconductor device 100 is a power semiconductor device.

Reference is made to FIG. 1A. An epitaxial layer 120 is formed on a substrate 110. In some embodiments, the substrate 110 can be single-crystal silicon substrate, and the material of the epitaxial layer 120 includes single-crystal silicon.

A body 122 is further formed in an upper portion of the epitaxial layer 120. In some embodiments, the body 122 is formed by performing an ion implantation process and a drive in process.

A first trench 121 is formed in the epitaxial layer 120. In some embodiments, the first trench 121 is formed by performing an etching process.

Then, a first dielectric layer 131, a second dielectric layer 132, and a third dielectric layer 133 are sequentially formed on the epitaxial layer 120, in which a second trench 134 is defined in the third dielectric layer 133, and the second trench 134 is located within the first trench 121. In some embodiments, the material of the first dielectric layer 131 includes silicon oxide, the material of the second dielectric layer 132 includes silicon nitride, and the material of the third dielectric layer 133 includes tetraethoxysilane (TEOS). The first dielectric layer 131 can be formed by performing a thermal oxidation process to the epitaxial layer 120. The second dielectric layer 132 and the third dielectric layer 133 are formed by performing one or more processes of physical vapor deposition and chemical vapor deposition.

Reference is made to FIG. 1B. A shield layer 140 is formed in the second trench 134. In some embodiments, the shield layer 140 is formed on the third dielectric layer 133, such as in the second trench 134 and covering the top surface of the third dielectric layer 133. The upper portion of the shield layer 140 is removed, and the remaining portion of the shield layer 140 is present in the second trench 134. The material of the shield layer 140 includes poly-Si. The shield layer 140 can be formed by performing one or more processes of physical vapor deposition and chemical vapor deposition. The upper portion of the shield layer 140 can be removed by, for example, performing one or more etching processes. The level of the top surface of the shield layer 140 is between the level of the top surface of the body 122 and the level of the bottom surface of the body 122.

Reference is made to FIG. 1C. The upper portion of the third dielectric layer 133 is removed, and the portion of the third dielectric layer 133 in the first trench 121 is remained, such that the upper portion 140u of the shield layer 140 is protruded from the third dielectric layer 133. In some embodiments, the third dielectric layer 133 can be removed by, for example, by a wet etching process.

Reference is made to FIG. 1D. A fourth dielectric layer 135 is formed on the upper portion 140u of the shield layer 140, such that the upper portion 140u of the shield layer 140 is covered by the fourth dielectric layer 135. In some embodiments, the material of the fourth dielectric layer 135 includes silicon oxide. The fourth dielectric layer 135 can be formed by performing a thermal oxidation process to the shield layer 140. In some embodiments, the second dielectric layer 132 can be utilized to protect the underlying structures, such as the first dielectric layer 131, during the process of thermal oxidizing the shield layer 140.

Reference is made to both FIGS. 1D and 1E. The upper portion of the second dielectric layer 132, e.g. the portion exceeded the top surface of the third dielectric layer 133, is removed, such that the level of the top surface of the second dielectric layer 132 and the level of the top surface of the third dielectric layer 133 are substantially the same. In some embodiments, the second dielectric layer 132 can be removed by, for example, by a wet etching process. In some embodiments, the upper portion of the second dielectric layer 132 is not removed and still remained on the first dielectric layer 131.

A gate 150 is formed in the third trench 138 and on the third dielectric layer 133. In some embodiments, a layer of gate material is formed in the third trench 138 and on the top surface of the first dielectric layer 131. Then the upper portion of the gate layer is removed to form the gate 150 in the third trench 138, which is in the epitaxial layer 120. As a result, the gate 150 is disposed on the second, third, and fourth dielectric layers 132, 133, and 135 and is directly in contact with the first dielectric layer 131. The material of the gate 150 may include poly-Si. The gate 150 can be formed by performing one or more processes of physical vapor deposition and chemical vapor deposition. The process of partially removing the gate layer can be an etching process.

Reference is made to FIG. 1F. A source 160 is formed on the body 122 (e.g. the epitaxial layer 120) surrounding the gate 150. The process of forming the source 160 includes an ion implantation process and a drive in process.

Reference is made to FIG. 1G. A fifth dielectric layer 136 is formed on the first dielectric layer 131 and the gate 150. In some embodiments, the material of the fifth dielectric layer 136 includes silicon oxide or silicon nitride. The fifth dielectric layer 136 can be formed by performing one or more processes of physical vapor deposition and chemical vapor deposition.

Then, a metal layer 171 is formed passing through the first and fifth dielectric layer 131 and 136 and is directly in contact with the body 122 and the source 160. For example, a contact window 129 is formed in the body 122, the first and fifth dielectric layers 131 and 136, and the source 160. The contact window 129 can be formed by etching. The metal layer 171 is formed in the contact window 129 and on the top surface of the fifth dielectric layer 136. The upper portion of the metal layer 171 is further removed, and the remaining portion of the metal layer 171 is located in the contact window 129. The material of the metal layer 171 includes aluminum, copper, tungsten, or the like. The metal layer 171 can be formed by electrochemical deposition process, physical vapor deposition, chemical vapor deposition, or the combination thereof. The upper portion of the metal layer 171 can be removed by a chemical mechanical planarization process.

In the semiconductor device 100, the substrate 110 functions as a drain. By disposing the shield layer 140 in the epitaxial layer 120, the shield layer 140 generates a pinch-off effect when the semiconductor device 100 is operated in reverse bias, such that the charge balance and the reduced surface field (RESURF) is generated and a smoother electric field distribution is generated between the substrate 110 and the gate 150. Therefore, the distance between the substrate 110 and the gate 150 needs to not be large enough to make the semiconductor device 100 have a larger breakdown voltage, and thus the on-resistance of the semiconductor device 100 will be reduced.

In addition, the fourth dielectric layer 135 between the gate 150 and the shield layer 140 is formed by thermal oxidizing the shield layer 140. Comparing with the traditional manufacturing method, the steps of manufacturing the semiconductor device 100 are further reduced thereby reducing the manufacturing cost.

The method is compatible with the relevant processes for manufacturing the traditional power semiconductor device, so the semiconductor device 100 can be manufactured by slightly adjusting the original processes. In addition, the shield layer 140 may be grounded or floating. The shield layer 140 makes the semiconductor device 100 has better capacitance characteristics. The reduced on-resistance and the better capacitance characteristics may reduce the on-off power loss of the semiconductor device 100.

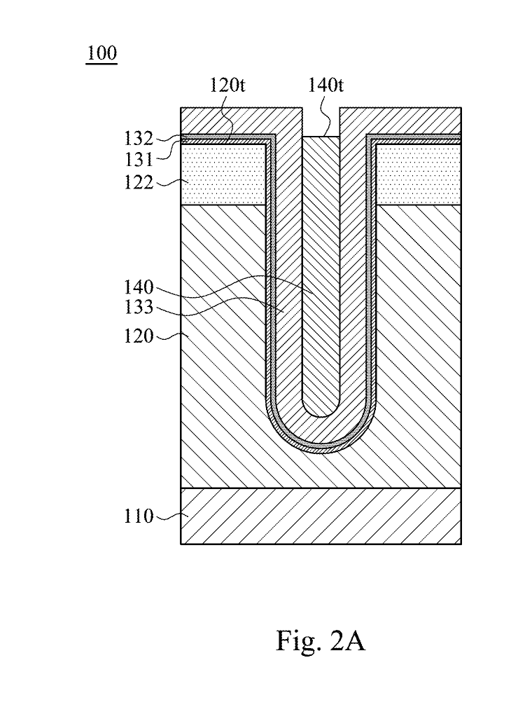

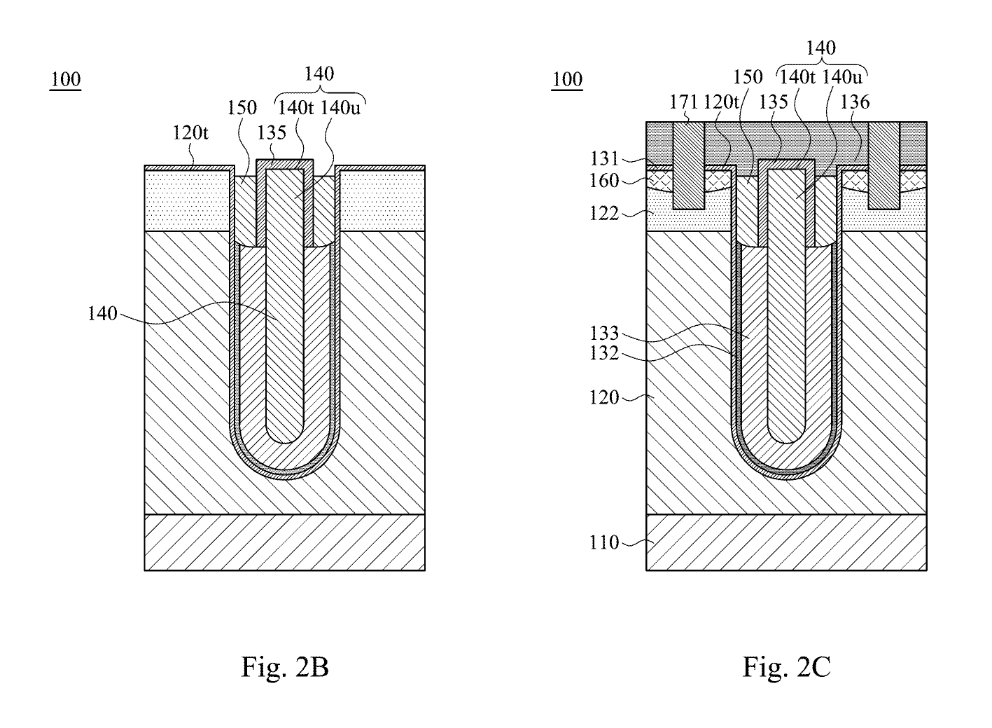

FIGS. 2A to 2C are cross-sectional views of intermediate steps of the method for manufacturing the semiconductor device 100 according to another embodiment of this disclosure. The embodiment is similar to the aforementioned embodiment, and differences are described below.

Reference is made to FIG. 2A. After the upper portion of the shield layer 140 is removed, the level of the top surface 140t of the oxidized shield layer 140 is lower than or the similar to the level of the top surface 120t of the body 122. Namely, the level of the top surface 140t of the shield layer 140 is between the level of the top surface 120t of the body 122 and the level of the bottom surface of the body 122. In this embodiment, the level of the top surface 140t of the shield layer 140 is substantially the same as the level of the top surface 120t of the body 122.

Reference is made to FIG. 2B. The level of the top surface 140t of the oxidized shield layer 140 is substantially the same as the level of the top surface 120t of the body 122. After the fourth dielectric layer 135 covers the shield layer 140, the level of the top surface of the fourth dielectric layer 135 is higher than the top surface of the level of the top surface 120t of the body 122. Therefore, the gate 150 is not disposed above the fourth dielectric layer 135 and is disposed at two sides of the fourth dielectric layer 135.

Reference is made to FIG. 2C. The fifth dielectric layer 136 and the metal layer 171 are formed on the structure. The semiconductor device 100 of the present embodiment is similar to the semiconductor device 100 in FIG. 1G. The difference is that the level of the top surface of the fourth dielectric layer 135 is higher than the level of the top surface 120t of the epitaxial layer 120, in which the sources 160 are formed in the body 122. Therefore, the gate 150 is not present on the top surface of the fourth dielectric layer 135.

Another aspect of the disclosure provides a semiconductor device 100. As illustrated in FIG. 1G, the semiconductor device 100 includes the substrate 110, the epitaxial layer 120, the dielectric layers 131, 132, 133, 135, and 136, the shield layer 140, the gate 150, the body 122, the source 160, and the metal layer 171.

The epitaxial layer 120 is disposed on the substrate 110. The dielectric layer 133 is disposed in the epitaxial layer 120. The shield layer 140 has an upper portion 140u and a lower portion 140d, in which the lower portion 140d is located in the third dielectric layer 133, and the upper portion 140u is protruded from the third dielectric layer 133. The fourth dielectric layer 135 covers the upper portion 140u of the shield layer 140. The gate 150 is disposed in the epitaxial layer 120 and on the third dielectric layer 133, in which at least a part of the fourth dielectric layer 135 is disposed between the upper portion 140u of the shield layer 140 and the gate 150. The source 160 is disposed in the epitaxial layer 120 surrounding the gate 150.

For example, at least a part of the gate 150 is above the upper portion 140u of the shield layer 140. Namely, a part of the gate 150 is disposed on the top surface of the fourth dielectric layer 135.

The material of the third dielectric layer 133 may include tetraethoxysilane, and the material of the fourth dielectric layer 135 may include silicon nitride.

For example, the first dielectric layer 131 is disposed between the epitaxial layer 120 and the third dielectric layer 133, in which the material of the first dielectric layer 131 includes silicon oxide. The first dielectric layer 131 is disposed between the source 160 and the gate 150 and on the top surface of the source 160.

For example, the second dielectric layer 132 is disposed between the first dielectric layer 131 and the third dielectric layer 133. The material of the second dielectric layer includes silicon nitride, but not limited to. In some embodiments, the second dielectric layer 132 is disposed between the source 160 and the gate 150.

For example, the body 122 is disposed in the epitaxial layer 120 surrounding the gate 150 and is disposed under the source 160. The first dielectric layer 131 is between the body 122 and the gate 150.

For example, the fifth dielectric layer 136 is disposed on the top surface of the gate 150 and on the top surface of the first dielectric layer 131 (e.g. on the source 160). The metal layer 171 penetrates the dielectric layers 131 and 136 and is directly in contact with the body 122 and the source 160.

Another aspect of the disclosure provides a semiconductor device 100. As shown in FIG. 2C, the semiconductor device 100 of the embodiment is similar to the semiconductor device 100 illustrated in FIG. 1G, and differences are described below.

The shield layer 140 has the top surface 140t. The epitaxial layer 120 has the top surface 120t. The level of the top surface of the fourth dielectric layer 135 is higher than the level of the top surface 120t of the epitaxial layer 120.

Meanwhile, the gate 150 is not disposed on the upper portion 140u of the shield layer 140. Namely, the gate 150 is not disposed on the top surface of the fourth dielectric layer 135.

In the semiconductor device, the substrate functions as a drain. By disposing the shield layer in the epitaxial layer, the shield layer generates a pinch-off effect when the semiconductor device is operated in reverse bias, such that the charge balance and the reduced surface field is generated and a smoother electric field distribution is generated between the substrate and the gate. Therefore, the distance between the substrate and the gate needs to not be large enough to make the semiconductor device have a larger breakdown voltage, and thus the on-resistance of the semiconductor device will be reduced.

In addition, the dielectric layer between the gate and the shield layer is formed by thermal oxidizing the shield layer. Comparing with the traditional manufacturing method, the steps of manufacturing the semiconductor device are further reduced thereby reducing the manufacturing cost.

The method is compatible with the relevant processes for manufacturing the traditional power semiconductor device, so the semiconductor device can be manufactured by slightly adjusting the original processes. In addition, the shield layer may be grounded or floating. The shield layer makes the semiconductor device has better capacitance characteristics. The reduced on-resistance and the better capacitance characteristics may reduce the on-off power loss of the semiconductor device.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a semiconductor device, the method comprising:
forming an epitaxial layer on a substrate;
forming a body in an upper portion of the epitaxial layer;
forming a first trench in the epitaxial layer;
forming a first dielectric layer, a second dielectric layer, and a third dielectric layer on the epitaxial layer sequentially, wherein the third dielectric layer defines a second trench, and the second trench is located within the first trench;
forming a shield layer in the second trench;
removing an upper portion of the third dielectric layer, such that an upper portion of the shield layer is protruded from the third dielectric layer;
forming a fourth dielectric layer covering the upper portion of the shield layer;
forming a gate on the third dielectric layer; and
forming a source in the epitaxial layer surrounding the gate.

2. The method for manufacturing the semiconductor device of claim 1, wherein the forming the fourth dielectric layer comprises:
performing a thermal oxidation process to the shield layer to form the fourth dielectric layer.

3. The method for manufacturing the semiconductor device of claim 1, wherein a level of a top surface of the shield layer is between a level of a top surface of the body and a level of a bottom surface of the body.

4. The method for manufacturing the semiconductor device of claim 1, further comprising:
removing an upper portion of the second dielectric layer before forming the gate on the third dielectric layer.

5. The method for manufacturing the semiconductor device of claim 1, wherein a level of a top surface of the fourth dielectric layer is higher than a level of a top surface of the epitaxial layer.

6. A semiconductor device, comprising:
a substrate;
an epitaxial layer disposed on the substrate;
a body disposed on an upper portion of the epitaxial layer;
a third dielectric layer disposed in a first trench of the epitaxial layer and defining a second trench;
a shield layer having an upper portion and a lower portion, wherein the lower portion is located in the second trench, and the upper portion is protruded from the third dielectric layer;
a fourth dielectric layer covering the upper portion of the shield layer;
a gate disposed in the epitaxial layer and on the third dielectric layer, wherein at least a part of the fourth dielectric layer is disposed between the upper portion of the shield layer and the gate; and
a source disposed in the epitaxial layer surrounding the gate.

7. The semiconductor device of claim 6, wherein at least a part of the gate is disposed above the upper portion of the shield layer.

8. The semiconductor device of claim 6, further comprising:
a first dielectric layer disposed between the epitaxial layer and the third dielectric layer, wherein the first dielectric layer comprises silicon oxide; and
a second dielectric layer disposed between the first dielectric layer and the third dielectric layer, wherein the second dielectric layer comprises silicon nitride.

9. The semiconductor device of claim 6, wherein the third dielectric layer comprises tetraethoxysilane (TEOS), and the fourth dielectric layer is formed by thermal oxidizing the shield layer.

10. The semiconductor device of claim 6, wherein a level of a top surface of the shield layer is between a level of a top surface of the body and a level of a bottom surface of the body.

11. The semiconductor device of claim 6, wherein a level of a top surface of the fourth dielectric layer is higher than a level of a top surface of the epitaxial layer.
